(19) United States
(12) Patent Application Publication
(10) Pub. No.: US 2011/0013241 A1
(43) Pub. Date: Jan. 20, 2011

(54) IMAGE READING APPARATUS AND IMAGE READING METHOD

(75) Inventor: Kensuke OHARA, Ebina-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJI XEROX CO., LTD., Tokyo (JP)

(21) Appl. No.: 12/816,082

(22) Filed: Jun. 15, 2010

(30) Foreign Application Priority Data
Jul. 16, 2009 (JP) 2009-167614

(51) Int. Cl. G03F 3/08

(52) U.S. Cl. 358/518

(57) ABSTRACT

An image reading apparatus includes: a read unit; an output unit; a determination unit that obtains a difference between the light values of the pixels sequentially outputted, the pixels being first pixel and second pixel arranged in first line and second line, respectively, at positions shifted from each other in the second scan direction, and that determines whether the difference exceeds a first threshold; a correction unit that corrects a chroma value of an adjacent pixel next to the first pixel when the difference exceeds the first threshold and when a predetermined condition is satisfied; and a position grasp unit that grasps the position of the first pixel whose lightness value and chroma value are outputted by the output unit. The determination unit performs at least any one of change of the first threshold and change of the second line when the position falls within a predetermined area.

### CROSS REFERENCE TO RELATED APPLICATIONS

This application is based on and claims priority under 35 USC §119 from Japanese Patent Application No. 2009-167614 filed Jul. 16, 2009.

### BACKGROUND

1. Technical Field

The present invention relates to an image reading apparatus, and an image reading method.

2. Related Art

An image processing apparatus has been known which includes a color discrimination unit that discriminates between color pixels and monochrome pixels on the basis of color components of an input image.

### SUMMARY

According to an aspect of the present invention, there is provided an image reading apparatus including: a read unit that reads an image on a document sheet by using plural light-receiving elements arranged in lines in a first scan direction while the document sheet is transported in a second scan direction; an output unit that sequentially outputs lightness values and chroma values of respective pixels on the basis of a result of the reading by the read unit; a determination unit that obtains a difference between the light values of the pixels sequentially outputted from the output unit, and that determines whether or not the difference exceeds a first threshold, the pixels being first pixel and second pixel arranged in a first line and a second line, respectively, at positions shifted from each other in the second scan direction; a correction unit that corrects a chroma value of an adjacent pixel next to the first pixel in the second scan direction to a chroma value within a predetermined range when the determination unit determines that the difference exceeds the first threshold and when a predetermined condition is satisfied; and a position grasp unit that grasps the position in the second scan direction of the first pixel whose lightness value and chroma value are outputted by the output unit, the determination unit performing at least any one of change of the first threshold to a different threshold and change of the second line to a different line when the position grasped by the position grasp unit falls within a predetermined area.

### BRIEF DESCRIPTION OF THE DRAWINGS

Exemplary embodiment(s) of the present invention will be described in detail based on the following figures, wherein:

FIG. 1 is a diagram showing an image reading apparatus to which the present exemplary embodiment is applied;

FIG. 2 is a diagram for illustrating the CCD image sensor;

FIG. 3 is a circuit block diagram showing the processor in detail;

FIG. 4 is a diagram showing a detailed configuration of the color misregistration correction circuit;

FIGS. 5A1 to 5B3 are diagrams for explaining the correction processing performed by the a-signal processor;

FIG. 6 is a diagram for explaining the second range;

FIG. 7 is a graph showing a correction example;

FIGS. 8A to 8C are diagrams for explaining processing for correcting two pixels;

FIGS. 9A to 9D are diagrams for showing states of the document feeder in reading of an image on a document sheet being transported;

FIG. 10 is a diagram for showing areas on the document sheet;

FIGS. 11A1 to 11B3 are diagrams for explaining the change of a threshold used in color misregistration correction;

FIGS. 12A to 12C are diagrams illustrating one exemplary embodiment of the automatic color detection circuit; and

FIG. 13 is a diagram showing an example of the area determination circuit.

### DETAILED DESCRIPTION

Hereinafter, an exemplary embodiment of the present invention will be described in detail with reference to the accompanying drawings.

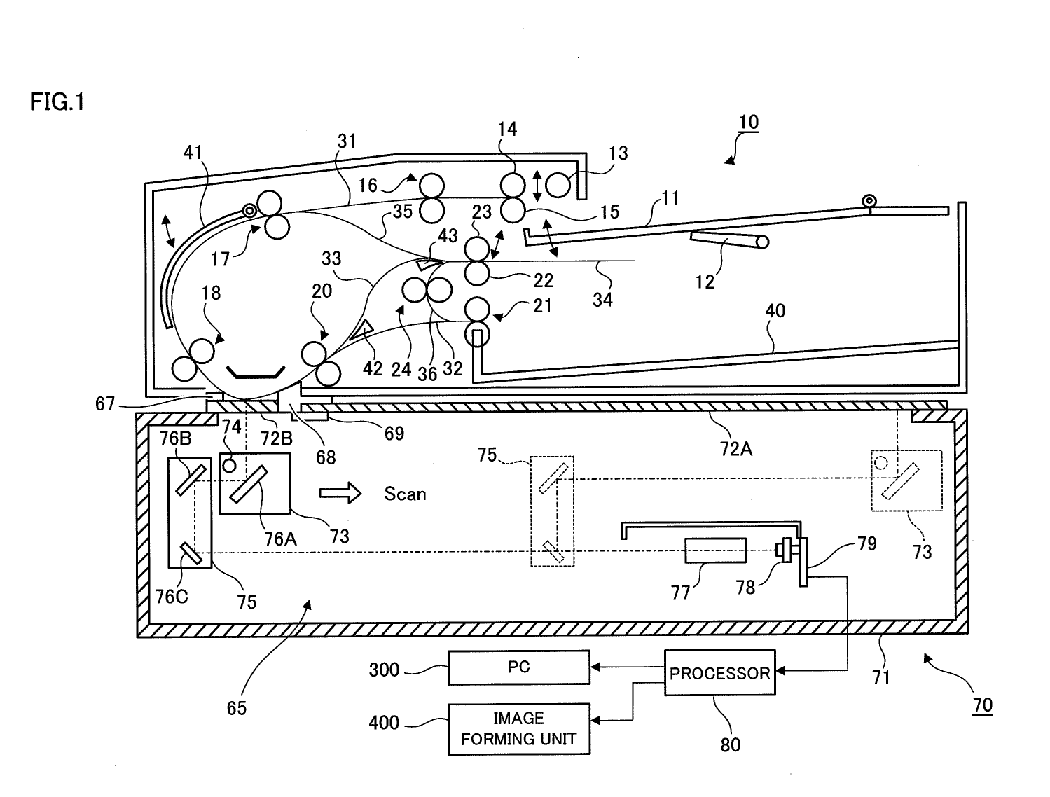

FIG. 1 is a diagram showing an image reading apparatus to which the present exemplary embodiment is applied. The image reading apparatus is roughly classified into: a document feeder 10 that sequentially transports stacked document sheets; a scanner 70 that reads images by scanning; and a processor 80 that processes images signals thus read.

The document feeder 10 includes: a document stacking part 11 that stacks thereon a bundle of document sheets composed of plural document sheets; a lifter 12 that raises and lowers the document stacking part 11; a transport roll 13 that transports the document sheets on the document stacking part 11 raised by the lifter 12; a feed roll 14 that transports further downstream the document sheets transported by the transport roll 13; and a retard roll 15 that separates one by one the document sheets fed through the transport roll 13.

A first transport path 31 is a transport path on which document sheets are first transported. Along the first transport path 31, take-away rolls 16, pre-registration rolls 17, registration rolls 18, out rolls 20, and a baffle 41 are provided. The take-away rolls 16 transport each of the document sheets thus separated one by one toward rolls on the downstream side thereof. The pre-registration rolls 17 transport the document sheet toward rolls on the downstream side thereof and form a loop of the document sheet. The registration rolls 18 restart rotation in conjunction with the read start timing after a temporary halt to feed the document sheet while performing registration adjustment on a second platen glass 72B to be described later. The out rolls 20 are provided downstream of the second platen glass 72B in a document transport direction and transport the read document sheet further downstream. The baffle 41 rotates about a pivot in accordance with a state of the loop of the document sheet being transported. Further, in a position facing a first guiding member 68 to be described later, a Contact Image Sensor (CIS) (not shown in the figure) is provided which reads the back surface of the document sheet being transported.

At the downstream side of the out rolls 20, the following are provided, a second transport path 32, a third transport path 33, a transport path switching gate 42, a document exit portion 40, first exit rolls 21, a fourth transport path 34, an inverter roll 22, an inverter pinch roll 23, a fifth transport path 35, a sixth transport path 36, second exit rolls 24, and an exit switching gate 43. The transport path switching gate 42 switches the transport path between the second and third transport paths 32 and 33. The document exit portion 40 stacks thereon read document sheets. The first exit rolls 21 output the document sheets toward the document exit portion 40. The fourth transport path 34 is a transport path on which each of the document sheets having passed through the third transport path 33 is switched back. The inverter roll 22 and the inverter pinch roll 23 are provided on the fourth transport path 34 and actually cause the document sheet to switch back. The fifth transport path 35 is used to introduce the document sheet having switched back on the fourth transport path 34 to the first transport path 31, which includes the pre-registration rolls 17 and the like, again. The sixth transport path 36 is used to output the document sheet thus switched back on the fourth transport path 34 to the document exit portion 40. The second exit rolls 24 are provided on the sixth transport path 36 and transport the document sheet, which is inverted and to be outputted, toward the first exit rolls 21. The exit switching gate 43 switches the transport path between the fifth and sixth transport paths 35 and 36.

The transport roll 13 is lifted up and held in a retracted position during standby, and is lowered to a nip position (document transport position) during document transportation so as to transport the uppermost document sheet on the document stacking part 11. The transport roll 13 and the feed roll 14 transport the document sheet by the engagement of feed clutches (not shown in the figure). The pre-registration rolls 17 form a loop of the document sheet by causing the leading end of the document sheet to abut against the registration rolls 18 being halted. On the loop formation, the registration rolls 18 move the leading end of the document sheet, having caught into the registration rolls 18, back to the nip position.

Once the above-mentioned loop is formed, the baffle 41 opens about the pivot and functions so as not to interfere with the loop formed in the document sheet. The take-away rolls 16 and the pre-registration rolls 17 hold the loop of the document sheet during reading. The loop formation allows adjusting the read timing and suppressing skew which accompanies document transport in reading, thus enhancing the alignment adjustment feature. In conjunction with the read start timing, the registration rolls 18 at rest start rotation and the document sheet is pressed onto the second platen glass 72B (to be described later), so that image data is read from below by use of a CCD image sensor 78 to be described later.

On completion of reading of a one-sided document sheet or on completion of simultaneous duplex reading of a double-sided document sheet, the transport path switching gate 42 is switched to guide the document sheet having passed through the out rolls 20 to the second transport path 32, and to output the document sheet to the document exit portion 40. In sequential reading of a double-sided document sheet, on the other hand, the transport path switching gate 42 is switched to guide the document sheet to the third transport path 33 in order to invert the document sheet. In the sequential reading of a double-sided document sheet, the inverter pinch roll 23 is released from a nip state thereof with feed clutches (not shown in the figure) turned off and retracted, and guides the document sheet to the fourth transport path 34. The inverter pinch roll 23 is thereafter placed in the nip state, and guides the document sheet inverted by the inverter roll 22 to the pre-registration rolls 17 as well as transports the document sheet, which is inverted and to be outputted, toward the second exit rolls 24 on the sixth transport path 36.

The scanner 70 supports the document feeder 10 from below. Specifically, the scanner 70 supports the document feeder 10 from below by way of a device frame 71. The scanner 70 includes, in the device frame 71 constituting a housing: a first platen glass 72A on which a document sheet whose image is to be read is placed at rest; and the second platen glass 72B that includes an opening portion for light used to read a document sheet being transported by the document feeder 10. A first guiding member 68 that guides the document sheet transported by the document feeder 10 is provided between the first and second platen glasses 72A and 72B. A second guiding member 67 that guides the document sheet transported by the document feeder 10 is provided on top of the second platen glass 72B. A first white reference plate 69 is disposed below the first guiding member 68 to extend in a first scan direction. The first white reference plate 69 has a white surface to be used as a reference in shading correction.

Moreover, the scanner 70 includes an image reading part 65. The image reading part 65 as an example of a read unit includes: a full-rate carriage 73 that stays still under the second platen glass 72B or performs scanning across the entire first platen glass 72A to read an image; and a half-rate carriage 75 that provides light obtained from the full-rate carriage 73 to an imaging forming part. The full-rate carriage 73 includes: a lamp 74 as an example of a light source that irradiates a document sheet with light; and a first mirror 76A that receives reflected light obtained from the document sheet. The half-rate carriage 75 includes a second mirror 76B and a third mirror 76C that provide the light obtained from the first mirror 76A to the imaging forming part.

The image reading part 65 also includes: an imaging forming lens 77 that optically reduces an optical image obtained from the third mirror 76C; the charge coupled device (CCD) image sensor 78 that photoelectrically converts an optical image formed by the imaging forming lens 77; and a driving substrate 79 on which the CCD image sensor 78 is mounted. An image signal obtained by the CCD image sensor 78 is transmitted to the processor 80 through the driving substrate 79. That is, in the scanner 70, an image is formed on the CCD image sensor 78 by use of a so-called minification optical system.

The image signal transmitted to the processor 80 is subjected to predetermined image processing and then transmitted to a personal computer (PC) 300 or an image forming unit (image forming device) 400. In the image forming unit 400, for example, an image is formed on a recording material such as a sheet by the electrophotographic system or the like. Here, the full-rate carriage 73 and the half-rate carriage 75 are moved in a second scan direction by a guide mechanism and a power transmission mechanism formed of a wire, a pulley and the like, which are not shown in the figure. Moreover, the full-rate carriage 73 and the half-rate carriage 75 are moved in the second scan direction by a common carriage motor (not shown in the figure).

When an image on a document sheet placed on the first platen glass 72A is read, the full-rate carriage 73 and the half-rate carriage 75 move in a scan direction (a direction indicated by an arrow in FIG. 1) at a ratio of 2:1. At this time, light from the lamp 74 of the full-rate carriage 73 is emitted to a reading target surface of the document sheet, and reflected light from the document sheet is reflected by the first mirror 76A, the second mirror 76B, and the third mirror 76C in this order and is guided to the imaging forming lens 77. The light guided to the imaging forming lens 77 then forms an image on the light-receiving surface of the CCD image sensor 78. Thereafter, the full-rate carriage 73 moves in the scan direction (the second scan direction) to read the next line of the document sheet. Document reading over one page is completed by repeating the above process over the entire document sheet.

Meanwhile, the second platen glass 72B is made of a transparent glass plate in the form of a long plate, for example. In the present exemplary embodiment, a document sheet transported by the document feeder 10 passes over the second platen glass 72B. In this event, the full-rate carriage 73 and the half-rate carriage 75 stay still in respective positions indicated by solid lines in FIG. 1. As mentioned in addition, the full-rate carriage 73 is located under the second platen glass 72B.

When an image on a document sheet transported by the document feeder 10 is read, reflected light from the first line of the document sheet forms an image at the imaging forming lens 77 through the first to third mirrors 76A, 76B, and 76C, and the image is read by the CCD image sensor 78. Specifically, image data corresponding to one line in the first scan direction of the document sheet being transported by the document feeder 10 is simultaneously processed by the CCD image sensor 78 which is a one-dimensional sensor. Then, the next line in the first scan direction of the document sheet is read. In the present exemplary embodiment, document reading over one page in the second scan direction is completed when the trailing end of a document sheet passes through a reading position of the second platen glass 72B after the leading end of the document sheet reaches the reading position of the second platen glass 72B.

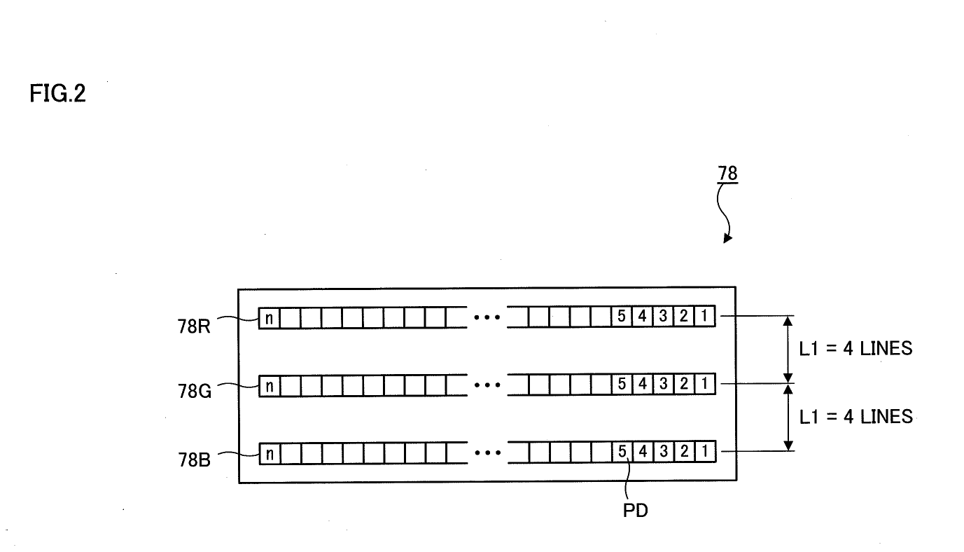

FIG. 2 is a diagram for illustrating the CCD image sensor 78.

The CCD image sensor 78 includes three line sensors 78R, 78G, and 78B for respective three colors R, G, and B so as to be capable of detecting components of three colors R, G, and B. Each of the line sensors 78R, 78G, and 78B is provided to extend in the first scan direction. Moreover, each of the line sensors 78R, 78G, and 78B includes plural photoelectric conversion elements (photodiodes (PDs), light-receiving elements) each of, for example, 7 μm×7 μm pixel size arranged to correspond to one line in the first scan direction. More specifically, the CCD image sensor 78 has three line sensors arranged at predetermined intervals, the line sensors each including n photoelectric conversion elements.

The line sensors 78R, 78G, and 78B are arranged at intervals of L1 μm. To correspond to this interval, the reading positions for the respective color components in the transport path of a document sheet are separated from one another by L2 μm in the second scan direction. Images of a document sheet in the respective reading positions (each of which is line image data corresponding to one line) are reduced to L1/L2 and imaged on the respective line sensors 78R, 78G, and 78B through the optical system shown in FIG. 1. More specifically, the distance L1 μm between adjacent line sensors corresponds to the distance L2 μm in a position where a document sheet is located prior to the collection of light by the imaging forming lens 77. Further specifically, the three line sensors 78R, 78G, and 78B simultaneously read a document sheet at positions separated from one another by L2 μm.

The line sensor 78R for R sequentially detects current flowing through n phototransistors for every line cycle (first scan cycle), and outputs an analog signal representing the density of pixels corresponding to one line (of n pixels), the n phototransistors constituting the line sensor R; the line sensor 78G for G also sequentially detects current flowing through n phototransistors for every line cycle, and outputs an analog signal representing the density of pixels corresponding to one line; and the line sensor 78B for B also sequentially detects current flowing through n phototransistors for every line cycle, and outputs an analog signal representing the density of pixels corresponding to one line.

Here, the interval L1 μm between the line sensors 78R, 78G and 78B, which corresponds to the interval L2 between the reading positions for the respective color components, corresponds to L1/7 (“7” indicates a pixel size) scan lines. For example, when the interval L2 between the reading positions for the respective color components is 169.2 μm and the interval L1 between the line sensors 78R, 78G and 78B is 28 μm, the number of scan lines is 4. Accordingly, if the document transport speed never changes, the output signal of R component and the output signal of G component have phase difference corresponding to L1/7 (4 lines in the above example); and the output signal of G component and the output signal of B component also have phase difference corresponding to L1/7.

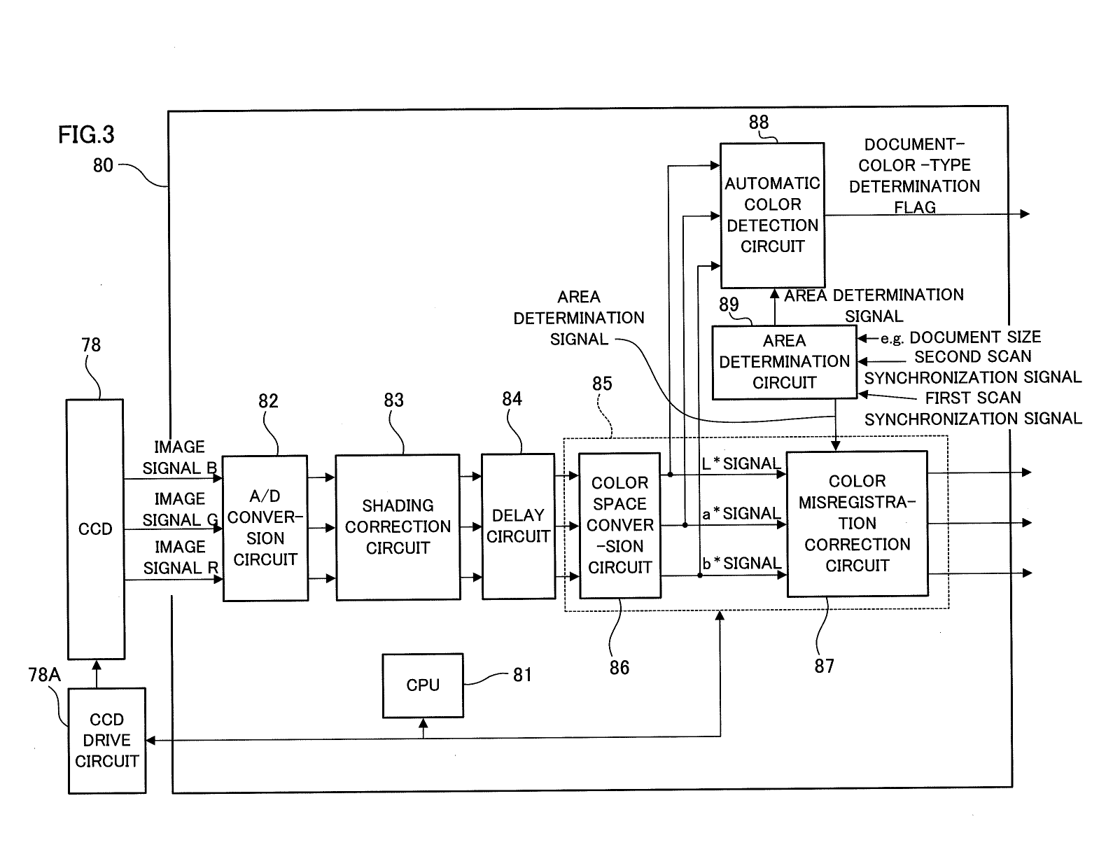

FIG. 3 is a circuit block diagram showing the processor 80 in detail. The processor 80 includes a CPU 81 that controls the entire processor 80, an A/D conversion circuit 82, a shading correction circuit 83, a delay circuit 84, an image processing circuit 85, an automatic color detection circuit 88, and an area determination circuit 89. Although not described above, the image reading apparatus of the present exemplary embodiment also includes a CCD drive circuit 78A that drives the CCD image sensor 78.

The CPU 81 sets the drive cycle of the CCD image sensor 78 (the line sensors 78R, 78G, and 78B) driven by the CCD drive circuit 78A, and controls the image processing circuit 85, for example. The A/D conversion circuit 82 converts RGB analog signals outputted from the CCD image sensor 78 to digital signals. The shading correction circuit 83 performs shading correction on the RGB digital signals outputted from the A/D conversion circuit 82. Then, the RGB digital signals subjected to shading correction by the shading correction circuit 83 are inputted to the delay circuit 84, and the resultant image signals outputted from the delay circuit 84 are inputted to the image processing circuit 85.

The delay circuit 84 delays the image signal R outputted from the shading correction circuit 83 by a delay time corresponding to the arrangement interval between the two line sensors 78R and 78B, i.e., 2*L2 (corresponding to 2*4=8 lines in the above example), and outputs the thus obtained image signal R having the same phase as that of the image signal B of B component. The delay circuit 84 also delays the image signal G outputted from the shading correction circuit 83 by a delay time corresponding to the arrangement interval between the two line sensors 78G and 78B, i.e., L2 (corresponding to 4 lines in the above example), and outputs the thus obtained image signal G having the same phase as that of the image signal B.

The image processing circuit 85 includes a color space conversion circuit 86 (an example of an output unit) and a color misregistration correction circuit 87. The color space conversion circuit 86 converts the RGB color space into the L*a*b color space. Specifically, the color space conversion circuit 86 converts multivalued image signals R, G, and B represented by the RGB color space into multivalued information represented by the L*a*b color space (“L*a*b” is hereinafter referred to as “Lab”), and thereby generates a signal L indicating lightness and signals a and b indicating chroma. The color misregistration correction circuit 87 corrects color misregistration caused on an edge portion of a monochrome image due to variation in the document transport speed.

The automatic color detection circuit 88 detects whether an image on a document sheet is a color image or a monochrome image on the basis of signals after color conversion performed by the color space conversion circuit 86. In other words, the automatic color detection circuit 88 detects whether the document is color or monochrome, and outputs a detection result. The area determination circuit 89 serving as one of position grasp units determines where the reading position, at which the CCD image sensor 78 performs reading, exists in a document sheet, and outputs a determination result as an area determination signal to the color misregistration correction circuit 87 and the automatic color detection circuit 88.

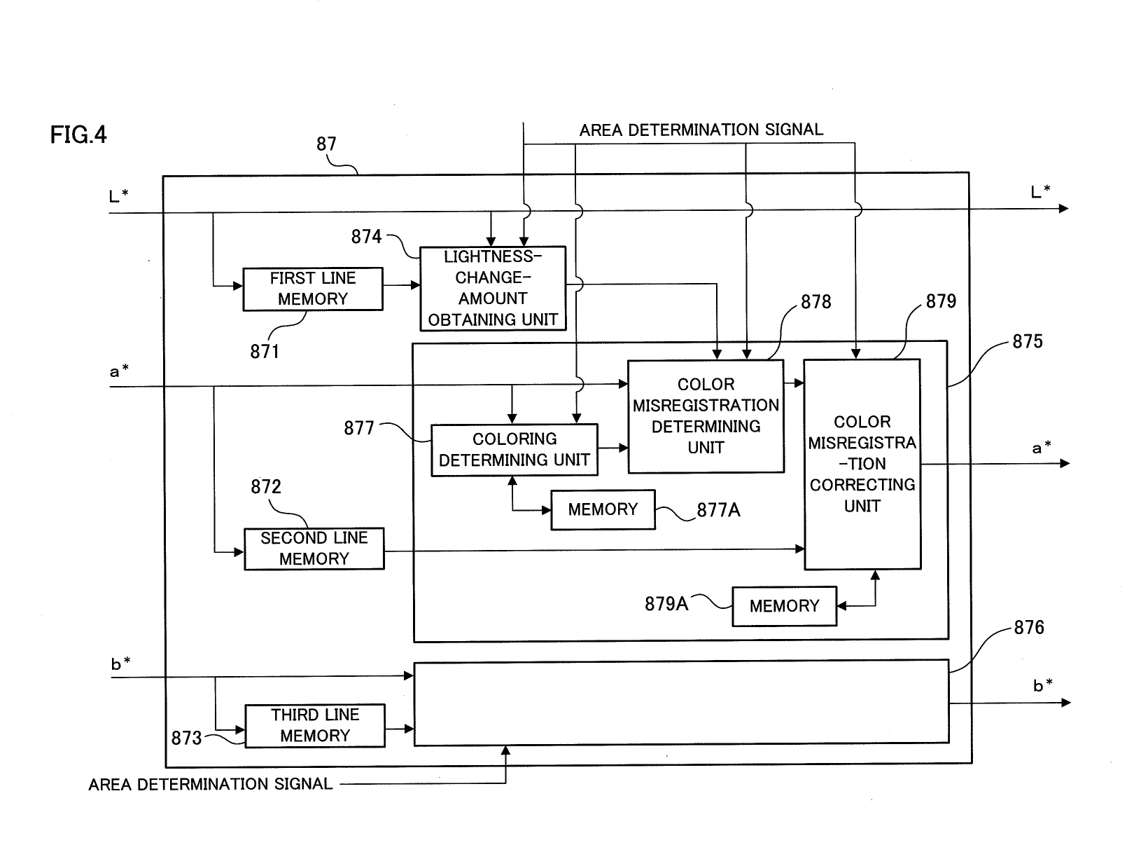

FIG. 4 is a diagram showing a detailed configuration of the color misregistration correction circuit 87.

As shown in FIG. 4, the color misregistration correction circuit 87 includes a first line memory 871, a second line memory 872, and a third line memory 873 that are used for storing, for each Lab, lightness values L and chroma values a and b of pixels corresponding to at least one line. The color misregistration correction circuit 87 also includes a lightness-change-amount obtaining unit 874 that obtains a change amount (difference) of lightness on the basis of an L signal inputted from the first line memory 871 and an L signal inputted thereto without passing through the first line memory 871.

More specifically, the lightness-change-amount obtaining unit 874 obtains a difference (a lightness change amount) between lightness L outputted from the color space conversion circuit 86 (see FIG. 3) and lightness L stored in the first line memory 871 (lightness L of the previous line). Further specifically, the lightness-change-amount obtaining unit 874 obtains a difference (a lightness change amount) between lightness L of a pixel outputted from the color space conversion circuit 86 and lightness L of a pixel which is adjacent to this pixel in the second scan direction, every time the color space conversion circuit 86 outputs lightness L. Here, the lightness-change-amount obtaining unit 874 outputs the difference thus obtained to a color misregistration determining unit 878. Moreover, as shown in FIG. 4, the signal L is outputted from the color misregistration correction circuit 87 without performing any signal processing thereon.

The color misregistration correction circuit 87 also includes an a-signal processor 875 that processes an a-signal, and a b-signal processor 876 that processes a b-signal. Note that, the a-signal processor 875 and the b-signal processor 876 have the same configuration, and hence the a-signal processor 875 is hereinafter mainly described.

The a-signal processor 875 includes a coloring determining unit 877, the color misregistration determining unit 878, and a color misregistration correcting unit 879.

The coloring determining unit 877 as an example of a second determination unit receives an a-signal from the color space conversion circuit 86 (see FIG. 3), and determines whether the received a-signal represents a chromatic color or an achromatic color. The coloring determining unit 877 also includes a memory 877A used for storing information of one bit on whether an a-signal of a different line, for which the determination is made prior to the determination for the line presently inputted, represents a chromatic color or an achromatic color. More specifically, the coloring determining unit 877 includes the memory 877A used for storing information, of several lines, on whether or not the chroma value represents an achromatic color.

The color misregistration determining unit 878 as an example of a determination unit and a first determination unit determines whether or not color misregistration occurs on the basis of the difference (the lightness change amount) obtained by the lightness-change-amount obtaining unit 874 and the result of the determination performed by the coloring determining unit 877.

The color misregistration correcting unit 879 corrects the chroma value of a pixel which is determined by the color misregistration determining unit 878 that color misregistration occurs. The color misregistration correcting unit 879 also includes a memory 879A used for storing information of one bit indicating that a pixel is corrected.

Here, the a-signal processor 875 corrects the chroma value stored in the second line memory 872 to a chroma value within a predetermined second range when the following are true: the lightness change amount obtained by the lightness-change-amount obtaining unit 874 falls within a predetermined first range; the chroma value stored in the second line memory 872 (the chroma value of an adjacent pixel) falls outside the predetermined second range; and the information stored in the memory 877A represents an achromatic color (when the chroma value of a second adjacent pixel adjacent to the adjacent pixel falls within a predetermined third range). The first and second ranges and the like are to be described later.

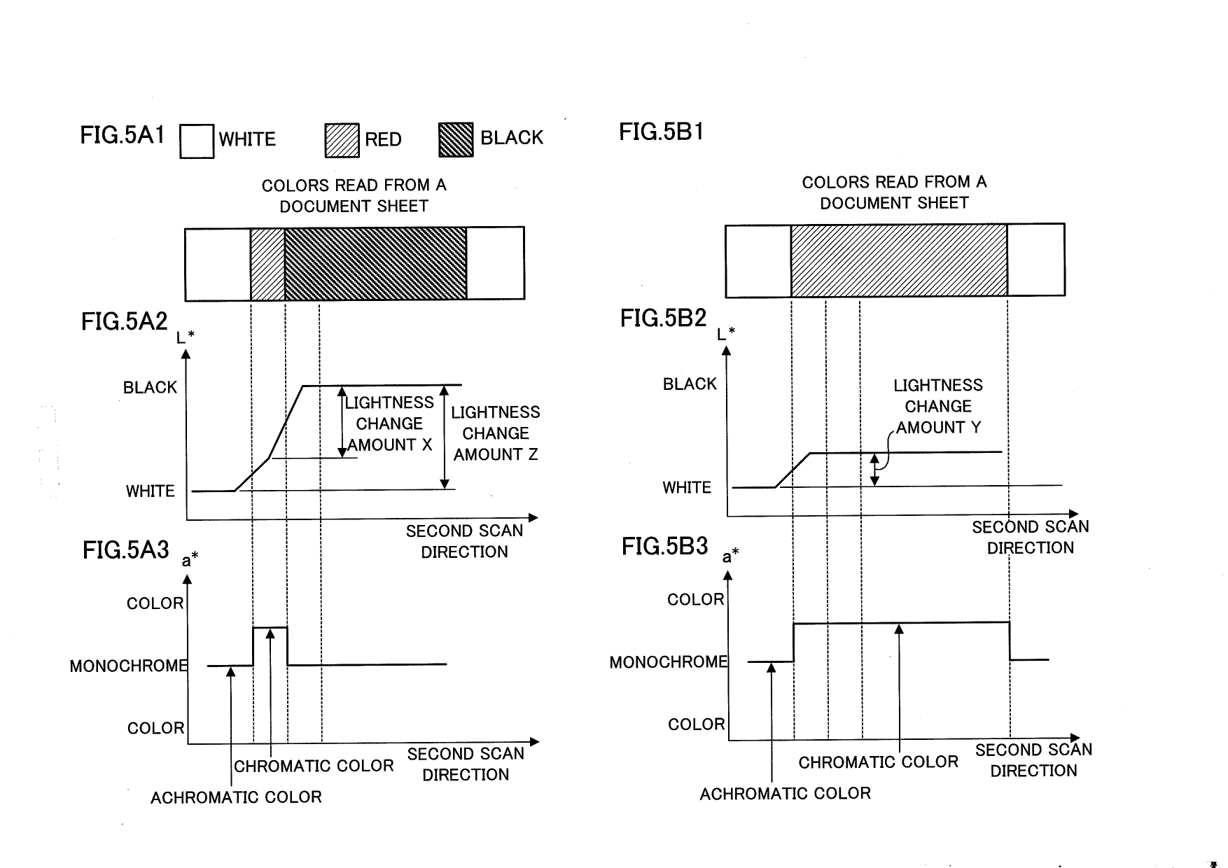

The aforementioned correction performed by the a-signal processor 875 is described in detail by referring FIGS. 5A1 to 5B3 (which are diagrams for explaining the correction processing performed by the a-signal processor 875). FIG. 5A1 indicates colors read from a document sheet, FIG. 5A2 is a graph for illustrating lightness values, and FIG. 5A3 is a graph for illustrating chroma values. In FIGS. 5B1 to 5B3, FIG. 5B1 indicates colors read from a document sheet, FIG. 5B2 is a graph for illustrating lightness values, and FIG. 5B3 is a graph for illustrating chroma values. In FIG. 5A2 and FIG. 5B2, the vertical axis denotes a lightness value L whereas the horizontal axis denotes a position in the second scan direction. In FIG. 5A3 and FIG. 5B3, the vertical axis denotes a chroma value a whereas the horizontal axis denotes a position in the second scan direction.

FIGS. 5A1 to 5B3 show a case where an edge portion of a black image printed on a document sheet is accidentally read as red having chroma due to variation in the document transport speed. More specifically, FIGS. 5A1 to 5B3 show a case where color misregistration of one pixel occurs. In this case, as shown in FIG. 5A2, a difference X (a lightness change amount X) occurs between a lightness value L in a portion read as red and a lightness value L in a portion read as black. Meanwhile, the chroma value a changes from a chroma value representing an achromatic color (monochrome) to a chroma value representing a chromatic color by the red pixel, and again changes to a chroma value representing an achromatic color.

The lightness value and chroma value, obtained when a document sheet having a red image originally formed thereon is read, are described here with reference to FIGS. 5B1 to 5B3. As shown in a graph of FIG. 5B2 indicating a lightness value L, when the document sheet having a red image originally formed thereon is read, a difference Y (a lightness change amount Y) occurs between a lightness value L in a portion read as white and a lightness value L in a portion read as red; however, the difference Y is smaller than the difference X of FIG. 5A2. More specifically, when color misregistration as shown in FIGS. 5A1 to 5A3 occurs, the lightness change amount X obtained is greater than the lightness change amount Y.

Meanwhile, when a black image is formed adjacent to a white image, a difference Z (a lightness change amount Z) occurs between a lightness value L in a portion read as white and a lightness value L in a portion read as black, as shown in FIG. 5A2. The lightness change amount Z is greater than the lightness change amount X. The present exemplary embodiment utilizes such a relationship to set the first range described above. In other words, the lower limit of the first range is set at the lightness change amount Y (an example of a first threshold) and the upper limit of the first range is set at the lightness change amount Z, which is represented by the following formula:

[lightness change amount Y<first range<lightness change amount Z].

In the case shown in FIGS. 5A1 to 5A3, the lightness change amount X falls within the first range, the chroma value stored in the second line memory 872 (the chroma value of the red portion, the chroma value of the adjacent pixel) falls outside the predetermined second range (the detail of which will be described later), and the information stored in the memory 877A (information on a line two lines ahead of the present line (information on the portion read as white)) is information representing an achromatic color. Thus, in the present exemplary embodiment, the chroma value stored in the second line memory 872 is corrected to a chroma value within the second range (the range of an achromatic color) by the color misregistration correcting unit 879 serving as a correction unit. In other words, the chroma value of a pixel read as red is corrected to a chroma value within the range of an achromatic color.

The aforementioned second range is now described.

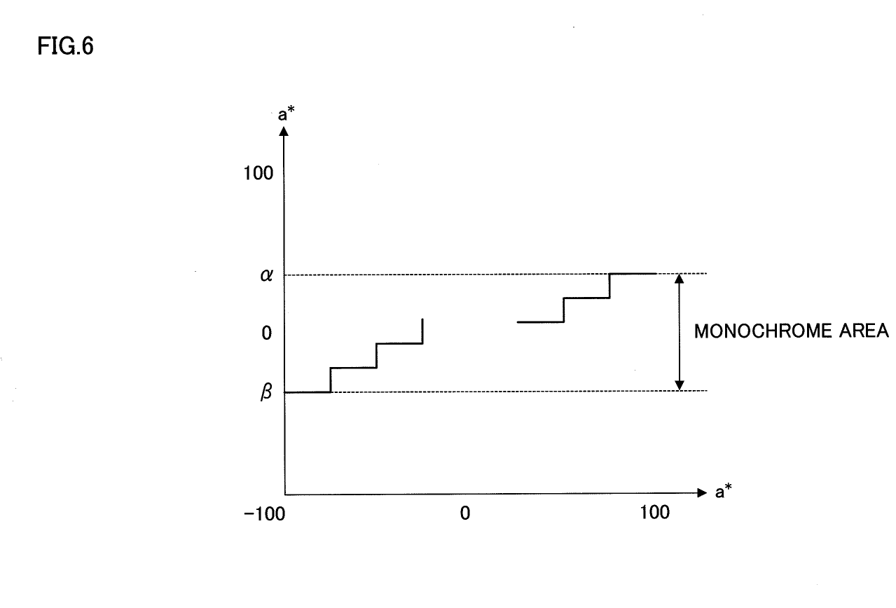

FIG. 6 is a diagram for explaining the second range.

FIG. 6 shows a graph including the vertical axis and the horizontal axis. Specifically, FIG. 6 shows a graph in which the horizontal axis denotes the chroma value of a pixel to be corrected whereas the vertical axis denotes the chroma value thereof after correction. Note that, a chroma value a is in the range of −100 to +100 here for the sake of simplicity of description. In the present exemplary embodiment, a chroma value which is a value not representing an achromatic color (monochrome) (i.e., which is not a value in the range from • to •) is converted to a chroma value representing an achromatic color. Here, the second range is represented by [•<second range<•] with the chroma values • and •. More specifically, a chroma value outside the second range is smaller than • or greater than •.

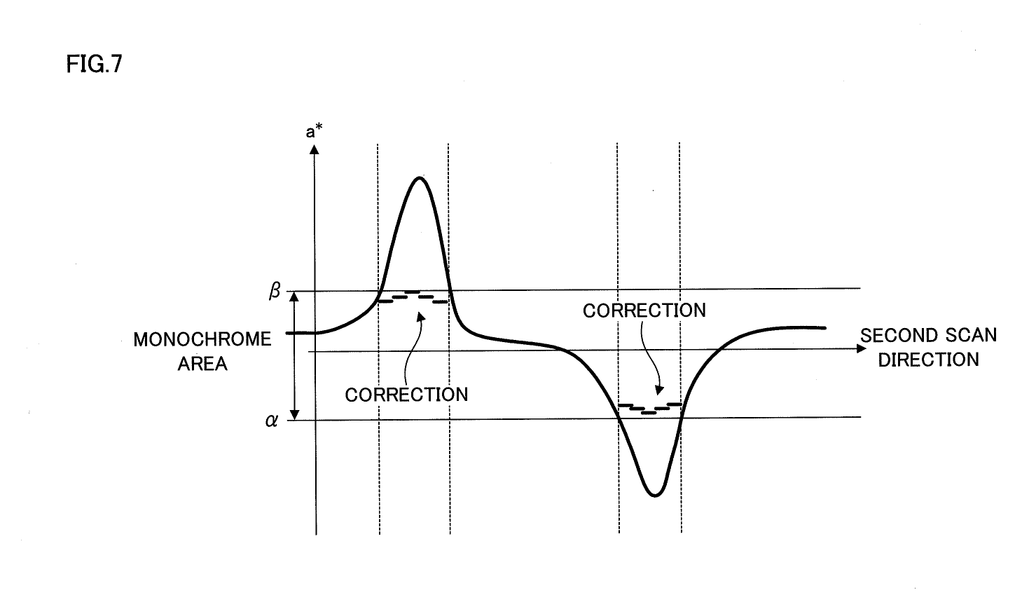

FIG. 7 is a graph showing a correction example. In the graph, the vertical axis denotes a chroma value a whereas the horizontal axis denotes a position in the second scan direction. In FIG. 7, the second range (a monochrome area) in which the chroma value represents an achromatic color is shown. FIG. 7 shows that a chroma value outside the second range (a chroma value representing a chromatic color) is corrected to a chroma value within the second range.

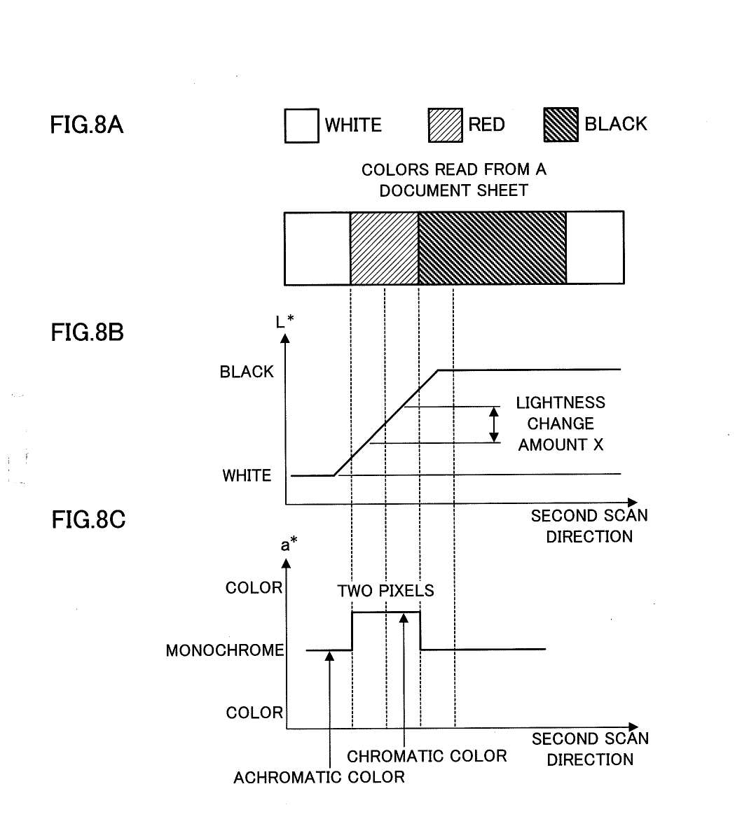

FIGS. 8A to 8C are diagrams for explaining processing for correcting two pixels. Specifically, FIG. 8A indicates colors read from a document sheet, FIG. 8B is a graph for illustrating lightness values, and FIG. 8C is a graph for illustrating chroma values.

FIGS. 8A to 8C show a case where, as similar to the case described above, an edge portion of a black image printed on a document sheet is read as red having chroma due to variation in the document transport speed. More specifically, FIGS. 8A to 8C show a case where color misregistration of two pixels occurs. In FIGS. 8A to 8C, a difference X (a lightness change amount X) also occurs between a lightness value L of the first one of pixels read as red and a lightness value L of the second one of the pixels read as red. Meanwhile, the chroma value a changes from a chroma value representing an achromatic color (monochrome) to a chroma value representing a chromatic color by the two red pixel, and again changes to a chroma value representing an achromatic color. Note that, the red portion is illustrated without any color variation in FIG. 8A; however, color gradually changes from thin red to black as the document sheet advances in the second scan direction in a case where the red portion is generated due to variation in the document transport speed.

In the case of the mode shown in FIGS. 8A to 8C, the first red pixel is the same as the case of FIGS. 5A1 to 5A3, and is to be corrected. In the correction, the color misregistration correcting unit 879 (see FIG. 4) stores, in the memory 879A, information of one bit indicating that the first red pixel is corrected. In the present exemplary embodiment, the chroma value of the second red pixel is also corrected by the color misregistration correcting unit 879 since the information indicating that the chroma of the first red pixel is corrected is stored in the memory 879A and the lightness change amount X obtained by the lightness-change-amount obtaining unit 874 falls within the first range.

Note that, an upper limit (for example, three) is set on the number of pixels to be corrected in correcting the chroma of pixels consecutive in the second scan direction as described above. This is because, if pixels to be corrected exist consecutively to a certain extent, it is highly likely that the chroma of the pixels is of the color originally read. Thus, no correction is performed on a pixel located beyond the upper limit, and on consecutive pixels subsequent to the pixel. Here, information to be stored in the memory 879A when a pixel appears on which no correction is to be performed, is information indicating that no correction is performed. Note that, the aforementioned upper limit may be changed in processing on an image signal acquired by reading of a leading end portion and a trailing end portion of a document sheet. For example, the upper limit may be increased.

The color misregistration described above is more likely to occur in reading of an image formed on an end portion of a document sheet on the upstream side thereof in the document transport direction, or of an image formed at one end portion of a document sheet on the downstream side thereof in the document transport direction.

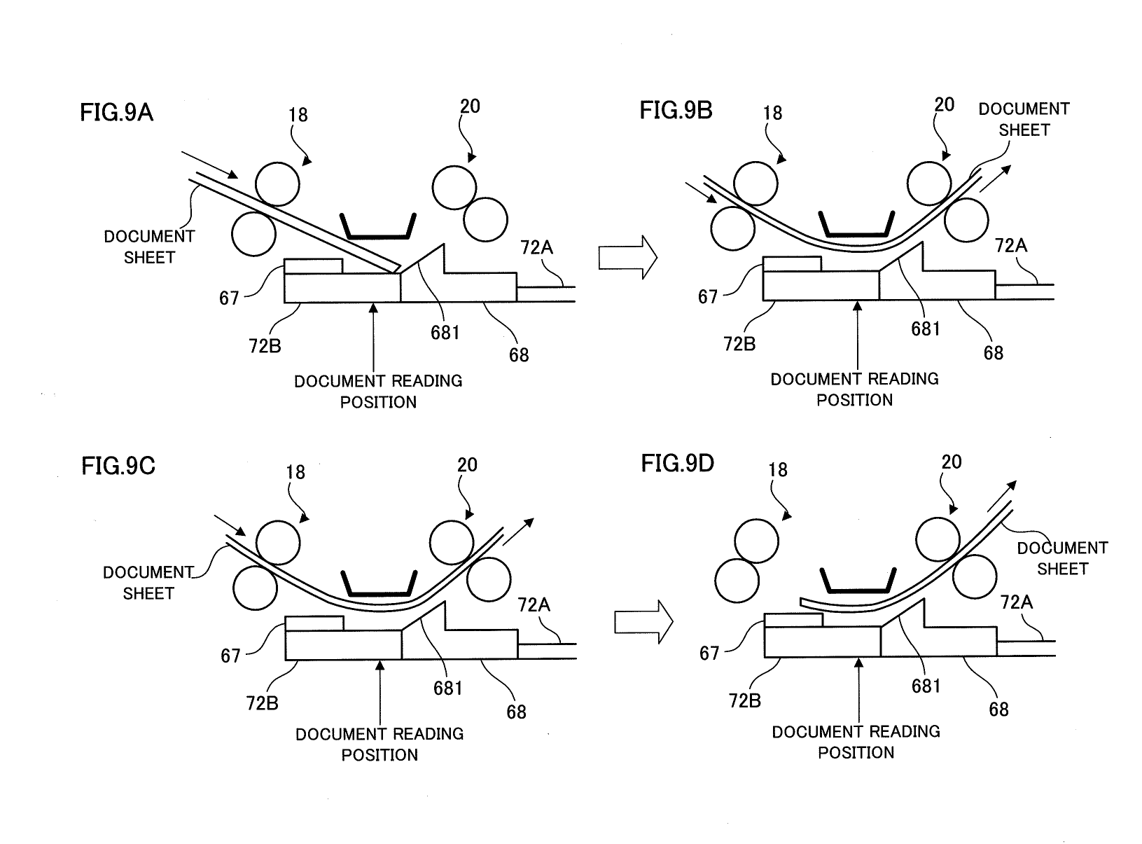

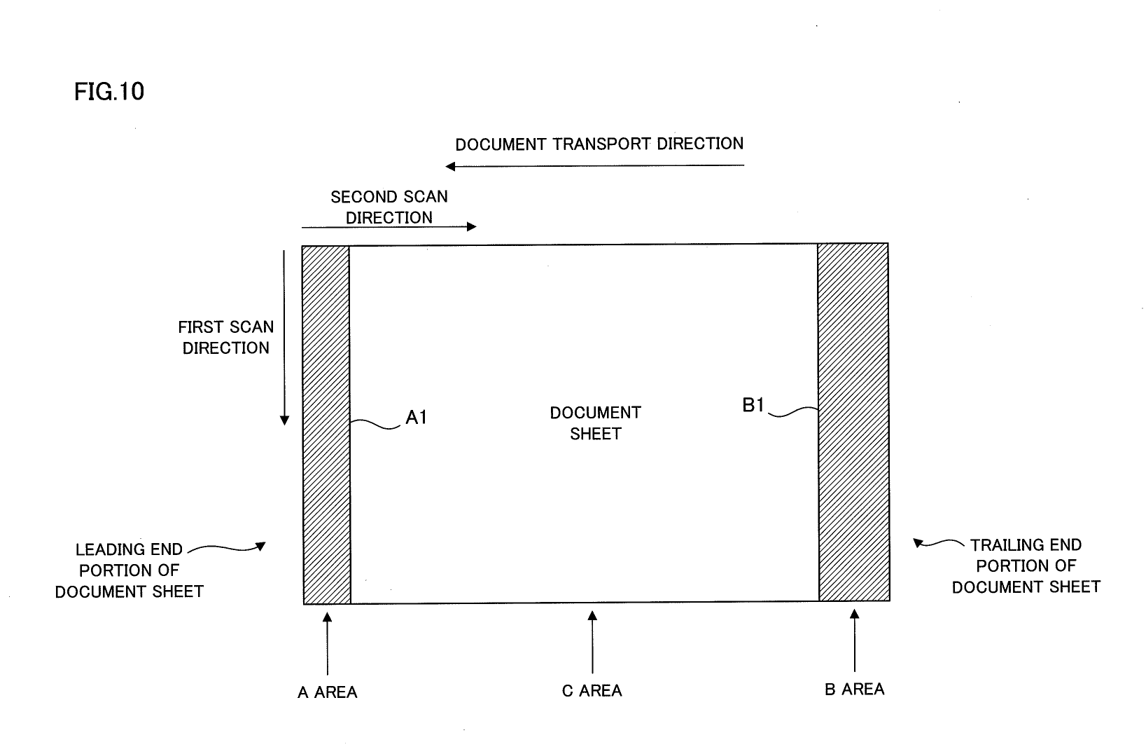

FIGS. 9A to 9D show states of the document feeder 10 (see FIG. 1) in reading of an image on a document sheet being transported. FIG. 10 shows areas on the document sheet.

FIG. 9A shows a state where the leading end portion of the document sheet passes through the registration rolls 18 and the document sheet is transported to the second platen glass 72B. The document sheet is first nipped between the registration rolls 18, and thereafter passes through the document reading position. At this time, the document sheet hits against the first guiding member 68 and the second guiding member 67. Moreover, the document sheet is caused to change its moving direction to a direction toward the out rolls 20 by a slope 681 formed in the first guiding member 68, thereby bending the leading end portion thereof. In this event, the document sheet is transported by the registration rolls 18 from when the leading end of the document sheet passes through the registration rolls 18 until when the leading end thereof hits against the first guiding member 68 or the second guiding member 67. In this case, the leading end of the document sheet is floated in the air, thus the document sheet may shift vertically.

The posture of the document sheet is greatly changed when the document sheet hits against the first guiding member 68 or the second guiding member 67, and when the document sheet is caused to change its moving direction to the direction toward the out rolls 20 by the slope 681 of the first guiding member 68. The leading end of the document sheet is floated in the air from when the document sheet is bent by the slope 681 until when the document sheet is nipped between the out rolls 20. In this case also, the document sheet may shift vertically. When the leading end of the document sheet is thereafter nipped between the out rolls 20, the vertical movement of the leading end of the document sheet is reduced, and thus the shift in the posture of the document sheet is suppressed. Consequently, the document transport speed is changed when the document sheet enters the reading position.

FIG. 9B shows a state where the leading end of the document sheet has passed through the out rolls 20. In this case, the document sheet is nipped between the out rolls 20 and between the registration rolls 18. Accordingly, the vertical movement of the document sheet is reduced and the shift in the posture of the document sheet is suppressed, resulting in a state of an extremely small speed change.

FIG. 9C shows a state where the trailing end of the document sheet reaches the upstream side of the registration rolls 18 but has not yet passed through the registration rolls 18. In this case, the document sheet is nipped between the out rolls 20 and between the registration rolls 18. Accordingly, the vertical movement of the document sheet is reduced and the shift in the posture of the document sheet is suppressed, resulting in a state of an extremely small speed change.

FIG. 9D shows a state where the trailing end of the document sheet has passed through the registration rolls 18. In this case, the document sheet is first released from the registration rolls 18 and then passes through the document reading position. The document sheet is thereafter caused to change its moving direction to the direction toward the out rolls 20 by the slope 681 of the first guiding member 68, and is then outputted. In this event, when the document sheet is released from the registration rolls 18, the trailing end of the document sheet is floated in the air, thus causing the document sheet to shift vertically to no small extent. The vertical movement then becomes larger in the subsequent transport process. After the trailing end of the document sheet passes through the second guiding member 67, the vertical movement is reduced. Consequently, the document transport speed is likely to be changed also when the trailing end of the document sheet passes through the document reading position.

To sum up the description mentioned above, as shown in FIG. 10, speed change of a document sheet is likely to occur in an A area which is a leading end portion of the document sheet, and is also likely to occur in a B area which is a trailing end portion of the document sheet. By contrast, the speed variation is reduced in a C area which is a central portion of the document sheet (between the A area and the B area).

Accordingly, when an image formed in the C area is being read, the three line sensors 78R, 78G, and 78B respectively outputs image signals in the same phase since a document sheet is transported at a predetermined speed. By contrast, when an image in the leading end portion of the document sheet or an image in the trailing end portion thereof is being read, speed variation is likely to occur as described above.

As a result, a delay time between the time when a document sheet passes through the reading position for R component and the time when the document sheet reaches the reading position for G component or the reading position for B component becomes shorter than the delay time generated by the delay circuit 84 (see FIG. 3), for example. This causes the phase of an image signal R to get ahead of the phase of an image signal B, or causes the phase of an image signal G to get ahead of the phase of the image signal B. Alternatively, the delay time between the time when the document sheet passes through the reading position for R component and the time when the document sheet reaches the reading position for G component or the reading position for B component becomes longer than the delay time generated by the delay circuit 84, for example. This causes the phase of the image signal R to get behind the phase of the image signal B, or causes the phase of the image signal G to get behind the phase of the image signal B.

Accordingly, when an image in the leading end portion of the document sheet or an image in the trailing end portion thereof is read, the three line sensors 78R, 78G, and 78B respectively output image signals R, G, and B in different phases although an image in a single portion of the document sheet is originally read. In this case, the image signals R, G, and B in different phases are inputted into the color space conversion circuit 86 (see FIG. 3) even if the delay correction is performed thereon on the basis of the delay time which is predetermined in accordance with the inter-line distance L2. This causes the color space conversion circuit 86 to output a Lab signal, which is different from a Lab signal that should be originally outputted, for the image in the single position of the document sheet. For example, the color space conversion circuit 86 accidentally outputs a Lab signal indicating a chromatic color for an image originally of an achromatic color.

In this respect, in the present exemplary embodiment, a threshold and the like used for color misregistration correction are changed when the color misregistration correction is performed by use of the color misregistration correction circuit 87 on image signals acquired by reading of a leading end portion and a trailing end portion of a document sheet. More specifically, a threshold and the like used in processing on image signals acquired by reading of a leading end portion and a trailing end portion of a document sheet are set different from a threshold and the like used in processing on image signals acquired by reading of a central portion of the document sheet. The change of a threshold and the like will be described below.

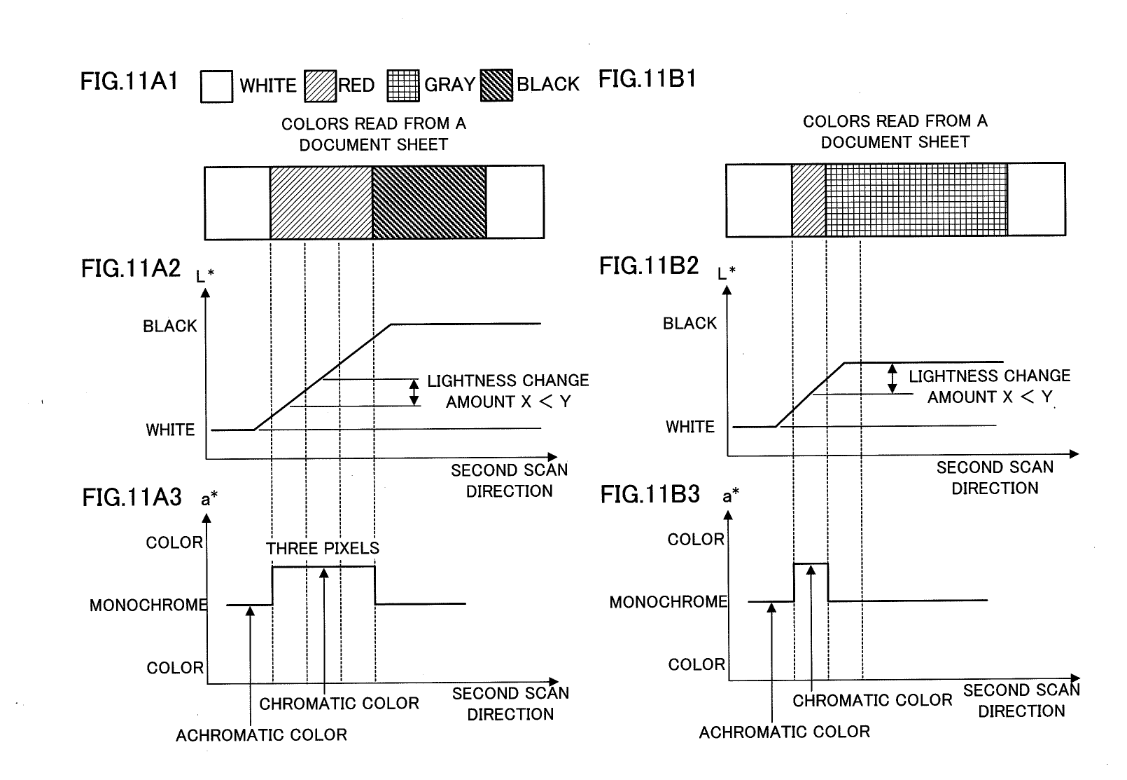

FIGS. 11A1 to 11B3 are diagrams for explaining the change of a threshold used in color misregistration correction. FIGS. 11A1 to 11A3 show a state where color misregistration of three lines occurs in the second scan direction due to variation in the document transport speed. Specifically, FIG. 11A1 indicates colors read from a document sheet, FIG. 11A2 is a graph for illustrating lightness values, and FIG. 11A3 is a graph for illustrating chroma values. FIGS. 11B1 to 11B3 are to be described later.

As described above, the variation in the transport speed is likely to occur in reading of a leading end portion and a trailing end portion of a document sheet. For this reason, an area in which color misregistration occurs is large in this case, as seen in the color misregistration of three lines shown in FIGS. 11A1 to 11A3. In the color misregistration correction, a lightness change amount X is firstly obtained as in the case described above. Next, it is judged (determined) whether or not the lightness change amount X falls within the first range [lightness change amount Y<first range<lightness change amount Z]. Meanwhile, as shown in FIG. 11A2, the inclination of the graph in the case where the area in which the color misregistration occurs is large is smaller than that in the case where the area in which the color misregistration occurs is small (see FIGS. 5A1 to 5A3, for example).

Thus, the lightness change amount X is accordingly small. As a result, the lightness change amount X falls outside the first range, so that no color misregistration correction is performed although color misregistration occurs. To cope with this, in the present exemplary embodiment, one of the thresholds of the first range is changed to a smaller one (which is a threshold of a smaller absolute value) in processing on image signals acquired by reading of a leading end portion and a trailing end portion of a document sheet. In other words, the “lightness change amount Y” is changed to a smaller one. This increases the possibility that the lightness change amount X falls within the first range, and that color misregistration correction is performed.

Alternatively, the second range [•<second range<•] may be narrowed in processing on image signals acquired by reading of a leading end portion and a trailing end portion of a document sheet. Specifically, for example, the value • (the absolute value of the value •) or the value • (the absolute value of the value •) is changed to a smaller one; or both the value • and the value • are changed to smaller ones. This makes the chroma value a likely to fall outside the second range, and increases the possibility that color misregistration correction is performed.

Further, as described above, the lightness-change-amount obtaining unit 874 obtains a difference between a lightness value L outputted from the color space conversion circuit 86 (see FIG. 3) and a lightness value L which is stored in the first line memory 871 and which is of a pixel (an adjacent pixel) adjacent to a target pixel (a pixel which is a target for determination). In other words, the lightness-change-amount obtaining unit 874 obtains a difference between a first lightness value L outputted from the color space conversion circuit 86 (see FIG. 3) and a second lightness value L of a second line adjacent to a first line at which the first lightness value L is obtained.

Alternatively, the lightness-change-amount obtaining unit 874 may obtain a difference between a lightness value L outputted from the color space conversion circuit 86 (see FIG. 3) and a lightness value L which is stored in the first line memory 871 and which is apart from the target pixel by a distance corresponding to two or more lines in the second scan direction. In other words, the lightness-change-amount obtaining unit 874 may obtain a difference (lightness change amount) between a lightness value L outputted from the color space conversion circuit 86 (see FIG. 3) and a lightness value L of a line two or more lines ahead of the present line. Then, it is determined whether the lightness change amount thus obtained falls within the first range [lightness change amount Y<first range<lightness change amount Z]. This also increases the possibility that the lightness change amount falls within the first range, and that color misregistration correction is performed.

FIGS. 11B1 to 11B3 show a case where a gray image is previously formed in a document sheet and where color misregistration of red occurs between the gray image and a white image in reading. Specifically, FIG. 11B1 indicates colors read from the document sheet, FIG. 11B2 is a graph for illustrating lightness values, and FIG. 11B3 is a graph for illustrating chroma values.

In a case where a gray image is formed on a document sheet, a maximum value of the lightness value L is smaller than a maximum value of the lightness value L in a case where a black image is formed thereon; accordingly, the inclination of the graph is small. In this case, the lightness change amount X in some cases may not exceed the lightness change amount Y which is the lower limit of the first range, so that no color misregistration correction is performed despite the occurrence of color misregistration. To cope with this, as described above, one of the thresholds of the first range (“lightness change amount Y”) is changed to a smaller one. This increases the possibility that the lightness change amount X falls within the first range. As a result, the possibility is increased that color misregistration correction is performed even when color misregistration occurs adjacent to the gray image as described above.

Next, the automatic color detection circuit 88 shown in FIG. 3 is described.

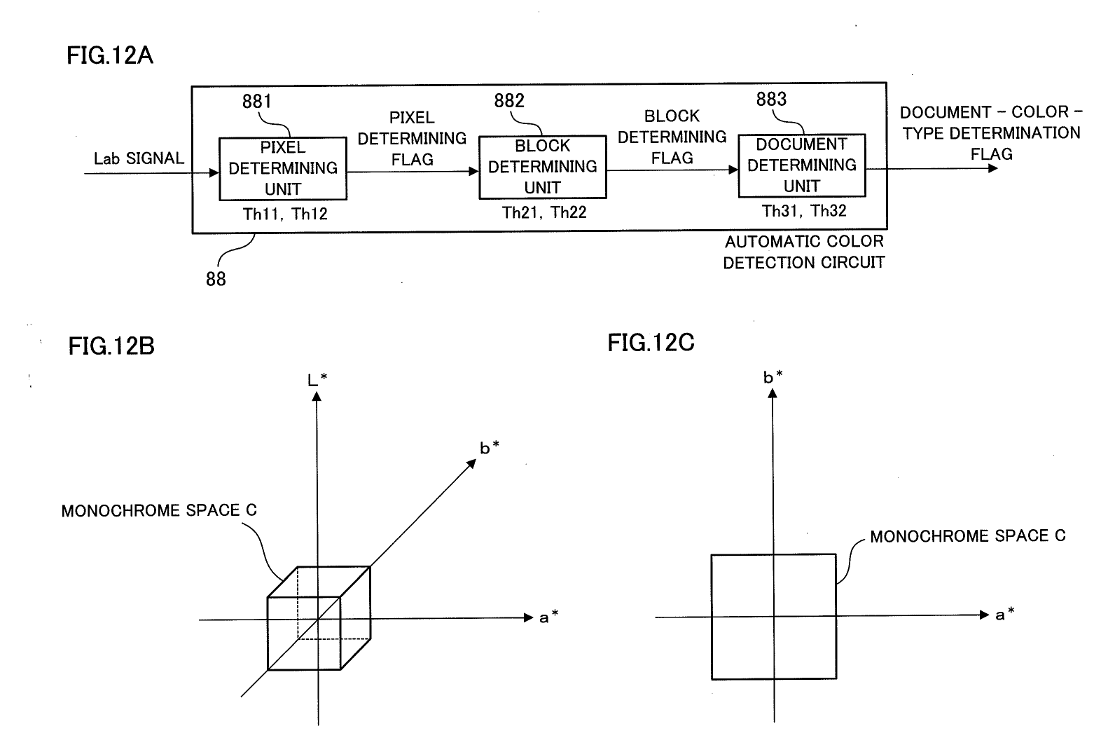

FIGS. 12A to 12C are diagrams illustrating one exemplary embodiment of the automatic color detection circuit 88. FIG. 12A is a circuit block diagram of the automatic color detection circuit 88. FIGS. 12B and 12C are diagrams for explaining color/monochrome discrimination processing performed by the automatic color detection circuit 88.

As shown in FIG. 12A, the automatic color detection circuit 88 includes: a pixel determining unit 881 that determines for each pixel constituting a document image whether the pixel is color or monochrome, and outputs an image determination flag; a block determining unit 882 that divides the image into plural blocks on the basis of the image determination flag outputted from the pixel determining unit 881, determines whether each block is color or monochrome, and outputs a block determination flag; and a document determining unit 883 that determines whether the image as a whole is color or monochrome on the basis of the block determination flag outputted from the block determining unit 882.

The pixel determining unit 881 as an example of a determination unit includes a memory not shown in the figure, and the memory holds therein a first pixel determination threshold Th11 and a second pixel determination threshold Th12 (>Th11). The block determining unit 882 also includes a memory not shown in the figure, and the memory holds therein a first block determination threshold Th21 and a second block determination threshold Th22 (>Th21). The document determining unit 883 also includes a memory not shown in the figure, and the memory holds therein a first document-color-type determination threshold Th31 and a second document-color-type determination threshold Th32 (>Th31).

When the automatic color detection circuit 88 receives a Lab signal from the color space conversion circuit 86 (see FIG. 3), the pixel determining unit 881 first compares the Lab signal of a target pixel (determination pixel) with the first pixel determination threshold Th11. Here, the first pixel determination threshold Th11 establishes a space C (a monochrome space C) in a Lab three-dimensional space region, as shown in FIGS. 12B and 12C. The space C corresponds to a color space representing an achromatic color.

Then, the pixel determining unit 881 determines whether the target pixel is a color pixel (a chromatic color pixel) or a monochrome pixel (an achromatic color pixel) in accordance with whether or not the value of the Lab signal of the target pixel falls within the space C. For example, the pixel determining unit 881 determines that the target pixel is a monochrome pixel if the value of the Lab signal of the target pixel falls within the space C, and determines that the target pixel is a color pixel if the value of the Lab signal of the target pixel falls outside the space C. The result of the determination by the pixel determining unit 881 is transmitted on a pixel basis to the block determining unit 882 as an image determination flag (for example, “L” indicates a color pixel and “H” indicates a monochrome pixel).

The block determining unit 882 serving as a grasp unit and a determination unit establishes a window block (region) of N pixels x M pixels (where N and M are positive integers) and measures the number of color pixels included in the window block, on the basis of the result of the determination (the pixel determination flag) performed by the pixel determining unit 881. The block determining unit 882 then compares the number of color pixels thus measured with the preset first block determination threshold Th21. More specifically, the block determining unit 882 determines whether or not the number of color pixels thus measured exceeds the first block determination threshold Th21. Thereby, the block determining unit 882 determines whether the window block is a color block (a chromatic color block) or a monochrome block (an achromatic color block).

To put it differently, the block determining unit 882 determines that a window block having the number of color pixels greater than the first block determination threshold Th21 is a color block. And the block determining unit 882 determines that a window block having the number of color pixels equal to or smaller than the first block determination threshold Th21 is a monochrome block. Note that, the window block described above is established so that a single pixel should not be included in plural window blocks. The result of the determination by the block determining unit 882 is transmitted on a block basis to the document determining unit 883 as a block determination flag (for example, “L” indicates a color block and “H” indicates a monochrome block).

The document determining unit 883 as an example of a result output unit measures the number of color blocks included in a detection area (to-be-read area) of a document sheet on the basis of the result of the determination (the block determination flag) performed by the block determining unit 882, and compares the number of color blocks with the first document-color-type determination threshold Th31. Thereby, the document determining unit 883 determines whether the document is a color document (i.e., a document with plural colors) or a monochrome document (i.e., a document with a single color), and outputs the determination result as a document-color-type determination flag. More specifically, the document determining unit 883 determines that a document having the number of color blocks greater than the first document-color-type determination threshold Th31 is a color document, and that a document having the number of color blocks equal to or smaller than the first document-color-type determination threshold Th31 is a monochrome document. The result of the determination by the document determining unit 883 is transmitted to the image forming unit 400 (see FIG. 1), for example, as a document-color-type determination flag (for example, “L” indicates a color document and “H” indicates a monochrome document).

On transmission of the determination result, the lab signal outputted from the color misregistration correction circuit 87 (see FIG. 3) is also transmitted to the image forming unit 400. Upon receipt of the determination result indicating that the document is monochrome, the image forming unit 400 forms an image on a sheet, which is a recording material, by use of a K (black) toner. On the other hand, upon receipt of the determination result indicating that the document is color, the image forming unit 400 forms an image on the sheet by use of toners of three colors, Y (yellow), M (magenta), and C (cyan), or toners of four colors, Y, M, C, and K.

Meanwhile, in the case of reading of a leading end portion and a trailing end portion of a document sheet, color misregistration is more likely to occur than in the case of reading of a central portion of the document sheet, as described above. Thus, in this case, the automatic color detection circuit 88 is likely to determine that the document is color. In other words, color misregistration may occur due to the document transport speed change, so that the document, which is originally monochrome, may be accidentally recognized as color. In this case, the image forming unit 400 handles an image on the document sheet, which is originally a monochrome image, as a color image, and accordingly forms an image by use of toners of three colors, Y, M, and C or toners of four colors, Y, M, C, and K.

To cope with this, the pixel determining unit 881 of the automatic color detection circuit 88 of the present exemplary embodiment changes the threshold from the first pixel determination threshold Th11 to the second pixel determination threshold Th12 (>Th11) in processing on image signals acquired by reading of the leading end portion and the trailing end portion of the document sheet. This increases the space C shown in FIG. 12B, and thus increases the possibility that the pixel determining unit 881 determines each pixel as a monochrome pixel. More specifically, the second pixel determination threshold Th12 increases any of: the range of the lightness L; the range of the chroma a; and the range of the chroma b, and thus allows increasing the possibility that the pixel determining unit 881 determines each pixel as a monochrome pixel. Further specifically, the second pixel determination threshold Th12 increases any of: the absolute value of the lower limit of the lightness L; the absolute value of the upper limit of the lightness L; the absolute value of the lower limit of the chroma a; the absolute value of the upper limit of the chroma a; the absolute value of the lower limit of the chroma b; and the absolute value of the upper limit of the chroma b, and thus allows increasing the possibility that the pixel determining unit 881 determines each pixel as a monochrome pixel.

Moreover, the block determining unit 882 changes the threshold from the first block determination threshold Th21 to the second block determination threshold Th22 (>Th21) in processing on image signals acquired by reading of the leading end portion and the trailing end portion of the document sheet. This makes the block determining unit 882 likely to determine that each window block is not a color block but a monochrome block even when color misregistration occurs in the leading end portion or the trailing end portion of the document sheet. Here, although description is given above of a case where both the pixel determination threshold and the block determination threshold are changed, only one of these thresholds may be changed instead.

Note that, the first document-color-type determination threshold Th31 used in the document determining unit 883 may also be changed to the second document-color-type determination threshold Th32 (>Th31). For example, the document determining unit 883 may use the first document-color-type determination threshold Th31 when reading a fixed document sheet (a document sheet placed on the first platen glass 72A), and may change the threshold to the second document-color-type determination threshold Th32 when reading a document sheet being transported by the document feeder 10. In other words, the document determining unit 883 may change the threshold from the first document-color-type determination threshold Th31 to the second document-color-type determination threshold Th32 in a situation where color misregistration is likely to occur.

As described above, in the present exemplary embodiment, the color misregistration correction circuit 87 changes a threshold and the like and the automatic color detection circuit 88 changes a threshold in processing on image signals acquired by reading of a leading end portion and a trailing end portion of a document sheet. Here, the color misregistration correction circuit 87 and the automatic color detection circuit 88 change a threshold and the like on the basis of an area determination signal outputted from the area determination circuit 89 (see FIG. 3).

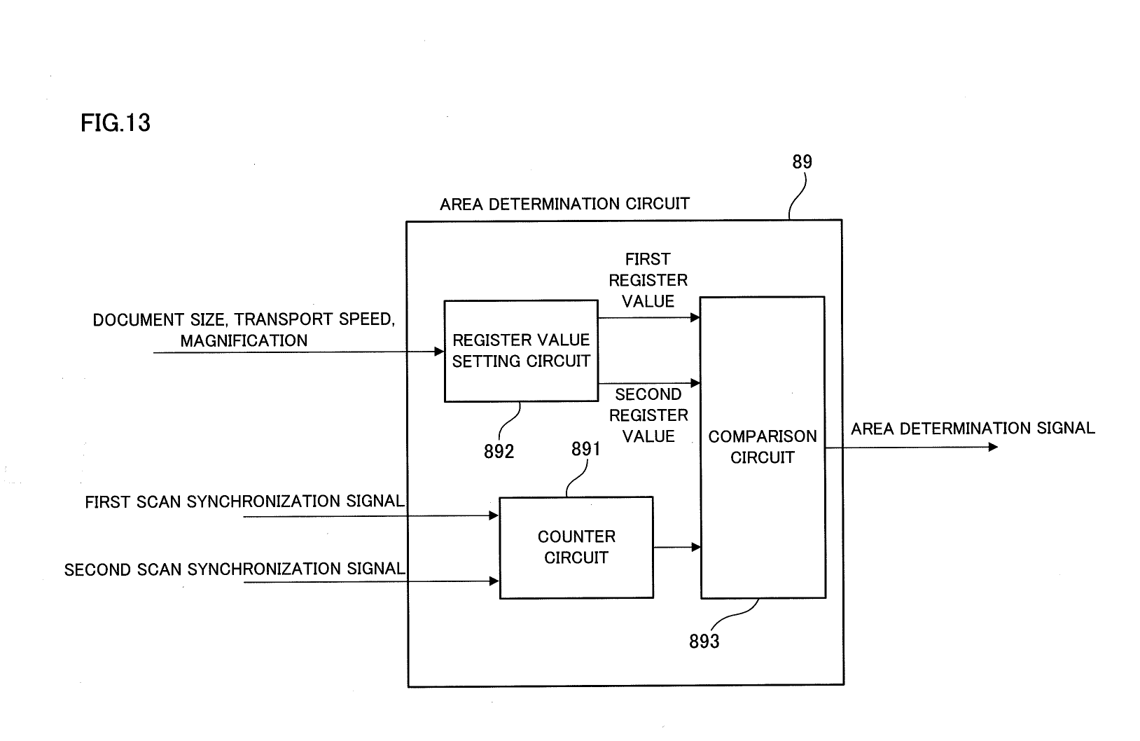

FIG. 13 is a diagram showing an example of the area determination circuit 89. As shown in FIG. 13, the area determination circuit 89 includes a counter circuit 891, a register value setting circuit 892, and a comparison circuit 893.

To the counter circuit 891, a second scan synchronization signal and a first scan synchronization signal (a line sync signal) are inputted. The second scan synchronization signal indicates a reference in the second scan direction, which corresponds to the document transport direction, in document reading. The first scan synchronization signal indicates a reference in the first scan direction, which is orthogonal to the second scan direction, in document reading. The counter circuit 891 counts up what line number each of inputted image signals R, B, and G is located at, the line number being counted since the second scan synchronization signal becomes available, that is to say, the counter circuit 891 calculates the reading position of each of the image signals R, B, and G with respect to a document reading start position, on the basis of the inputted second scan synchronization signal and first scan synchronization signal.

To the register value setting circuit 892, information on a document size detected by a sensor not shown in the figure, information on a transport speed, and information on a magnification (a ratio Q of an output size Q2 to a read size Q1=Q2/Q1) and the like are inputted.

The register value setting circuit 892 calculates a line number (a first register value) at which an end A1 of a document sheet (see FIG. 10) reaches the reading position, the end A1 being located on the upstream side in the transport direction of an area located at a leading end portion of the document sheet (an A area: see FIG. 10). Specifically, the register value setting circuit 892 calculates a line number (the first register value) at which the end A1 reaches the reading position, the line number being counted since the second scan synchronization signal becomes available. The register value setting circuit 892 also calculates a line number (a second register value) at which an end B1 of the document sheet (see FIG. 10) reaches the reading position, the end B1 being located on the downstream side in the transport direction of an area located at a trailing end portion of the document sheet (a B area: see FIG. 10). Specifically, the register value setting circuit 892 calculates a line number (the second register value) at which the end B1 reaches the reading position, the line number being counted since the second scan synchronization signal becomes available. The register value setting circuit 892 then outputs the first register value and second register value thus calculated to the comparison circuit 893.

The comparison circuit 893 compares the first and second register values, and the counter value outputted from the counter circuit 891, and outputs the area determination signal as a comparison result. Specifically, the comparison circuit 893 outputs, for example, an area determination signal T from when reading is started until when the end Al reaches the reading position. Then, the comparison circuit 893 outputs, for example, an area determination signal N from when the end A1 passes through the reading position until when the end B1 passes through the reading position. Thereafter, the comparison circuit 893 outputs the area determination signal T again after the end B1 reaches the reading position. In the present exemplary embodiment, the color misregistration correction circuit 87 changes the threshold and the like and the automatic color detection circuit 88 changes the threshold while the comparison circuit 893 outputs the area determination signal T.

The foregoing description of the exemplary embodiments of the present invention has been provided for the purposes of illustration and description.

It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. An image reading apparatus comprising:
a read unit that reads an image on a document sheet by using a plurality of light-receiving elements arranged in lines in a first scan direction while the document sheet is transported in a second scan direction;
an output unit that sequentially outputs lightness values and chroma values of respective pixels on the basis of a result of the reading by the read unit;
a determination unit that obtains a difference between the light values of the pixels sequentially outputted from the output unit, and that determines whether or not the difference exceeds a first threshold, the pixels being first pixel and second pixel arranged in a first line and a second line, respectively, at positions shifted from each other in the second scan direction;
a correction unit that corrects a chroma value of an adjacent pixel next to the first pixel in the second scan direction to a chroma value within a predetermined range, when the determination unit determines that the difference exceeds the first threshold and a predetermined condition is satisfied; and
a position grasp unit that grasps the position in the second scan direction of the first pixel whose lightness value and chroma value are outputted by the output unit, wherein
the determination unit performs at least any one of change of the first threshold to a different threshold and change of the second line to a different line when the position grasped by the position grasp unit falls within a predetermined area.

2. The image reading apparatus according to claim 1, wherein the determination unit changes at least any one of the first threshold and the second line when the position of the first pixel in the second scan direction falls within an area corresponding to any one of a leading end portion and a trailing end portion of the document sheet.

3. The image reading apparatus according to claim 1, wherein the determination unit performs at least any one of change of the first threshold to a threshold whose absolute value is smaller than an absolute value of the first threshold, and change of the second line to a line which is farther from the first line including the first pixel than the second line is.

4. The image reading apparatus according to claim 1, wherein the correction unit corrects the chroma value of the adjacent pixel to a chroma value within the predetermined range, when the determination unit determines that the difference exceeds the first threshold, the chroma value of the adjacent pixel falls outside a predetermined second range, and a chroma value of a second adjacent pixel next to the adjacent pixel in the second scan direction falls within a predetermined third range.

5. An image reading apparatus comprising:
a read unit that reads an image on a document sheet by using a plurality of light-receiving elements arranged in a line in a first scan direction while the document sheet is transported in a second scan direction;
an output unit that sequentially outputs lightness values and chroma values of respective pixels on the basis of a result of the reading by the read unit;
a first determination unit that obtains a difference between the light values of the pixels sequentially outputted from the output unit, and that determines whether or not the difference exceeds a first threshold, the pixels being first pixel and second pixel arranged, respectively, at positions shifted from each other in the second scan direction;
a second determination unit that determines whether or not a chroma value of an adjacent pixel next to the first pixel in the second scan direction falls within a predetermined second range;
a correction unit that corrects the chroma value of the adjacent pixel to a chroma value within a predetermined range, when the first determination unit determines that the difference exceeds the first threshold, the second determination unit determines that the chroma value of the adjacent pixel falls outside the second range, and a predetermined condition is satisfied; and
a position grasp unit that grasps the position in the second scan direction of the adjacent pixel targeted for the determination by the second determination unit, wherein
the second determination unit changes at least one of an upper limit and a lower limit of the second range when the position grasped by the position grasp unit falls within a predetermined area.

6. The image reading apparatus according to claim 5, wherein the second determination unit changes at least one of the upper limit and the lower limit of the second range when the position of the adjacent pixel in the second scan direction falls within an area corresponding to any one of a leading end portion and a trailing end portion of the document sheet.

7. The image reading apparatus according to claim 5, wherein the second determination unit changes at least one of the upper limit and the lower limit of the second range so as to narrow the second range.

8. The image reading apparatus according to claim 5, wherein the correction unit corrects the chroma value of the adjacent pixel to the chroma value within the predetermined range, when the first determination unit determines that the difference exceeds the first threshold, the second determination unit determines that the chroma value of the adjacent pixel falls outside the second range, and a chroma value of a second adjacent pixel next to the adjacent pixel in the second scan direction falls within a predetermined third range.

9. An image reading apparatus comprising:
a read unit that reads an image on a document sheet by using a plurality of light-receiving elements arranged in a first scan direction while the document sheet is transported in a second scan direction;
an output unit that outputs a chroma value of each pixel on the basis of a result of the reading by the read unit;
a determination unit that determines whether or not the chroma value outputted from the output unit exceeds a predetermined chroma value; and
a position grasp unit that grasps a position in the second scan direction of each pixel targeted for the determination by the determination unit, wherein
the determination unit changes the predetermined chroma value to a different chroma value when the position grasped by the position grasp unit falls within a predetermined area.

10. The image reading apparatus according to claim 9, wherein the determination unit changes the predetermined chroma value to the different chroma value when the position grasped by the position grasp unit falls within an area corresponding to any one of a leading end portion and a trailing end portion of the document sheet.

11. The image reading apparatus according to claim 9, wherein the determination unit changes the predetermined chroma value to a chroma value whose absolute value is larger than an absolute value of the predetermined chroma value.

12. An image reading apparatus comprising:
a read unit that reads an image on a document sheet by using a plurality of light-receiving elements arranged in a first scan direction while the document sheet is transported in a second scan direction;
an output unit that outputs chroma values of respective pixels on the basis of a result of the reading by the read unit;
a grasp unit that establishes a plurality of regions and grasps the number of pixels having the chroma values exceeding a predetermined chroma value within each of the regions;
a determination unit that determines, for each of the regions, whether or not the number grasped by the grasp unit exceeds a predetermined number; and
a position grasp unit that grasps a position in the second scan direction of each of the regions targeted for the determination by the determination unit, wherein
the determination unit changes the predetermined number to a different number when the position grasped by the position grasp unit falls within a predetermined area.

13. The image reading apparatus according to claim 12, wherein the determination unit changes the predetermined number to the different number when the position grasped by the position grasp unit falls within an area corresponding to any one of a leading end portion and a trailing end portion of the document sheet.

14. The image reading apparatus according to claim 12, wherein the determination unit changes the predetermined number to a number larger than the predetermined number.

15. The image reading apparatus according to claim 12, further comprising a result output unit that judges whether the document sheet is color or monochrome on the basis of a result of the determination performed by the determination unit, and outputs a result of the judgment.

16. An image reading method for an image reading apparatus that includes a read unit that reads an image on a document sheet by using a plurality of light-receiving elements arranged in lines in a first scan direction while the document sheet is transported in a second scan direction, and an output unit that sequentially outputs lightness values and chroma values of respective pixels on the basis of a result of the reading by the read unit, the method comprising:
obtaining a difference between the light values of the pixels sequentially outputted, and that determines whether or not the difference exceeds a first threshold, the pixels being first pixel and second pixel arranged in first line and second line, respectively, at positions shifted from each other in the second scan direction;
correcting a chroma value of an adjacent pixel next to the first pixel in the second scan direction to a chroma value within a predetermined range, when the difference is determined as to exceed the first threshold and a predetermined condition is satisfied;
grasping the position in the second scan direction of the first pixel whose lightness value and chroma value are outputted, and
performing at least any one of change of the first threshold to a different threshold and change of the second line to a different line when the position being grasped falls within a predetermined area.
